(19) United States
(12) Patent Application Publication
(10) Pub. No.: US 2009/0140238 A1
(43) Pub. Date: Jun. 4, 2009

(54) FLAT SCREEN DETECTOR

(76) Inventors: Christoph Brabec, Linz (AT); Georg Wittmann, Herzogenaurach (DE)

Correspondence Address: SCHIFF HARDIN, LLP;PATENT DEPARTMENT, 6600 SEARS TOWER, CHICAGO, IL, 60606-6473, US

(21) Appl. No.: 11/997,590

(22) PCT Filed: Aug. 4, 2006
(86) PCT No.: PCT/EP2006/065063

§ 371 Date: Jul. 17, 2008

(30) Foreign Application Priority Data
Aug. 8, 2005 (DE) 10 2005 037 290.2

(51) Int. Cl. H01L 31/0256; H01L 31/0224

(52) U.S. Cl. 257/40; 257/431; 257/43; 257/E31.003; 257/E31.124

(57) ABSTRACT

A flat screen detector has a substrate with a transistor matrix thereon, a photodetector, and a passivation layer. The photodetector includes a structured first electrode including a number of sub-electrodes, a second electrode, and a photoactive layer between the first and second electrodes. The passivation layer is located between the substrate having the transistor matrix and the first electrode.

### BACKGROUND OF THE INVENTION

1. Field of the Invention

The invention concerns a flat panel detector of the type having a substrate carrying a transistor matrix and a photodetector.

2. Description of the Prior Art

With a flat panel detector, light striking the flat panel detector is transduced into electrical signals that can be converted into an image data set with a suitable evaluation device. The image associated with the image data set can be visualized with a viewing apparatus.

Current flat panel detectors are a combination of a pixelated photodetector and a transistor matrix.

The pixelated photodetector essentially has two electrodes and a semiconductor layer arranged between the two electrodes. One of the electrodes is structured such that it comprises a plurality of sub-electrodes insulated from one another that are respectively associated with a pixel of an image to be acquired with the flat panel detector.

For acquiring an image with the flat panel detector, the light distribution associated with the image thus penetrates the electrode facing toward the light distribution, so the electrode is therefore produced from material that is at least semi-transparent. Furthermore, the semiconductor layer in connection with the two electrodes transduces the light distribution into electrical signals that are present at the individual sub-electrodes of the structured electrode.

The transistor matrix is embedded in a substrate. Each of the individual transistors of the transistor matrix is in turn associated with one of the pixels of the image to be acquired with the flat panel detector and is respectively electrically connected with one of the sub-electrodes of the structured electrode. The transistors of the transistor matrix are controlled and read out with a control device. The read signals are relayed to the evaluation device.

Prevalent flat panel detectors are produced by the structured electrode being directly applied on the substrate embodying the transistor matrix. One disadvantage of this embodiment is that the structure of the laminar photodetector must be adapted to the structure of the substrate, which is determined by the transistors of the transistor matrix. Thin-film transistors typically are used as transistors for the transistor matrix. However, if a transistor matrix with transistors based on a different transistor technology is used, the process for the application of the laminar photodetector must be adapted to this transistor technology.

### SUMMARY OF THE INVENTION

An object of the invention is to provide a flat panel detector for which manufacture is simplified even given the use of different substrates for the transistor matrix.

This object is achieved in accordance with the invention by a flat panel detector having a substrate with a transistor matrix; a photodetector with a structured first electrode that includes a number of sub-electrodes, the detector further having a second electrode and a photoactive layer arranged between the two electrodes; and a passivation layer arranged between the first electrode and the substrate.

The basis of the inventive flat panel detector is thus to not build the photodetector directly on the substrate with the transistor matrix, but rather to initially provide the substrate with the passivation layer and to build the photodetector on this passivation layer. The photodetector is spatially separated from the substrate via the passivation layer. It is thus possible for the photodetector to be arranged vertically above the individual transistors, so the surface of the photodetector is enlarged. The filling factor of the photodetector thus can be increased.

Capacitive couplings between the transistors of the transistor matrix and the structured first electrode and/or the electrical conductor traces can also be reduced by the vertical design. FET panels from the LCD industry are preferably used as substrates with transistor matrices.

Due to the passivation layer it is possible to achieve a design of the photodetector surface that is designed identically, with the design being substantially independent of the employed substrate or, respectively, from the employed technology for the transistor matrix. The passivation layer therefore enables the photodetector to be executed independent of the employed substrate or independently of the employed technology for the transistor matrix, to the greatest possible extent. The surface of the substrate in particular does not to be compatible with the chemistry of the photodetector.

The passivation layer is preferably applied on the substrate by means of printing techniques. The inventive flat panel detector can thereby be manufactured in a particularly cost-effective manner.

The photodetector can then be applied particularly simply on the passivation layer when, according to a variant of the inventive flat panel detector, the passivation layer can be planarized and/or structured (in particular photostructured) on the side facing towards the first electrode. For example, the passivation layer can be provided particularly simply with vias with which the individual sub-electrodes of the first electrode are contacted through the passivation layer with a respective transistor of the substrate possessing the transistor matrix. A via is a vertical opening filled with an electrically-conductive material that electrically connects different layers with one another.

An inorganic semiconductor material is typically used for the photoactive layer. However, according to a particularly preferred embodiment of the inventive flat panel detector, the photodetector is an inorganic photodetector having a photoactive layer formed of an organic semiconductor material. Organic photodetectors can be produced relatively simply by the organic semiconductor being applied with printing technology methods. Semiconductor materials for organic photodetectors include photoresists, PBO, BCB etc. Moreover, organic photodetectors exhibit a relatively high compatibility with various technologies of the transistor matrix of the substrate Various technologies of the transistor matrix comprise a-Si, LTpolySi, pentacene, polymers, ZnO or chalcopyrite FETs. The corresponding semiconductors from the solution are processed for the manufacture of a chalcopyrite FET.

An organic photodetector normally has an electron/hole-blocking layer in addition to the photoactive layer (that, for example, with P3HT/PCBM, CUPc/PTCBI, ZNPC/C60, conjugated polymer components or fullerene components. Electron/hole-blocking layers are known from the technology for organic LEDs. A suitable organic material for the electron- blocking layer is, for example, TFB.

A critical parameter for the image detection is what is known as the dark current of a photodetector.

### BRIEF DESCRIPTION OF THE DRAWINGS

FIG. 1 through FIG. 4 show various manufacturing stages of a flat panel detector with an organic photodetector in accordance with the invention.

### DESCRIPTION OF THE PREFERRED EMBODIMENTS

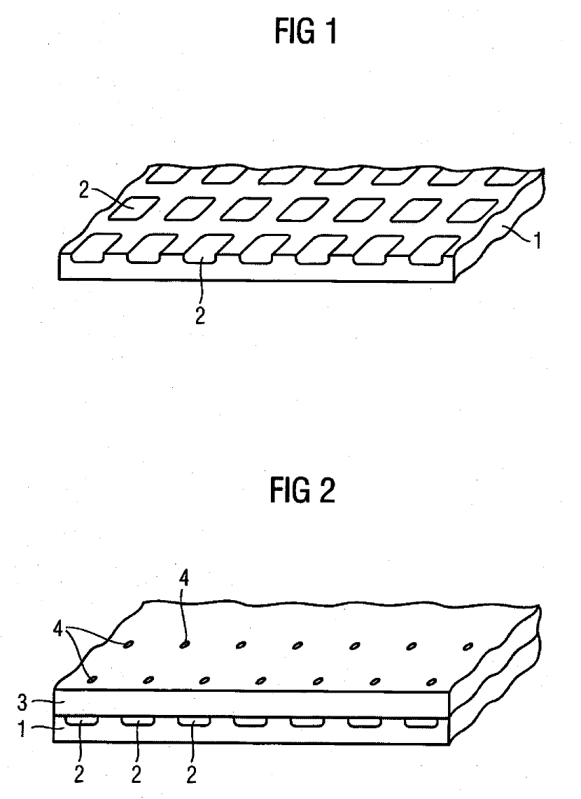

FIGS. 1 through 4 illustrate the manufacture of an inventive flat panel detector with an organic photodetector (oPD).

FIG. 1 shows in section a substrate 1 with a transistor matrix comprising a plurality of transistors 2. In the case of the present exemplary embodiment the individual transistors 2 are a-Si FETs that have been produced by means of thin-film technology. Each of the transistors 2 is associated with a pixel of an image to be acquired with the flat panel detector.

A passivation layer 3 (shown in FIG. 2) is subsequently applied on the substrate 1. In the case of the present exemplary embodiment the passivation layer 3 (which comprises a significantly electrically-insulating material) was applied on the substrate 1 by means of known printing techniques, subsequently structured (as shown in FIG. 2) by means of photo-techniques and finally planarized. Via the structuring the passivation layer 3 receives vias 4 (thus vertical holes) that are filled with an electrically-conductive material. The individual transistors can be contacted through the passivation layer 3 via the vias 4.

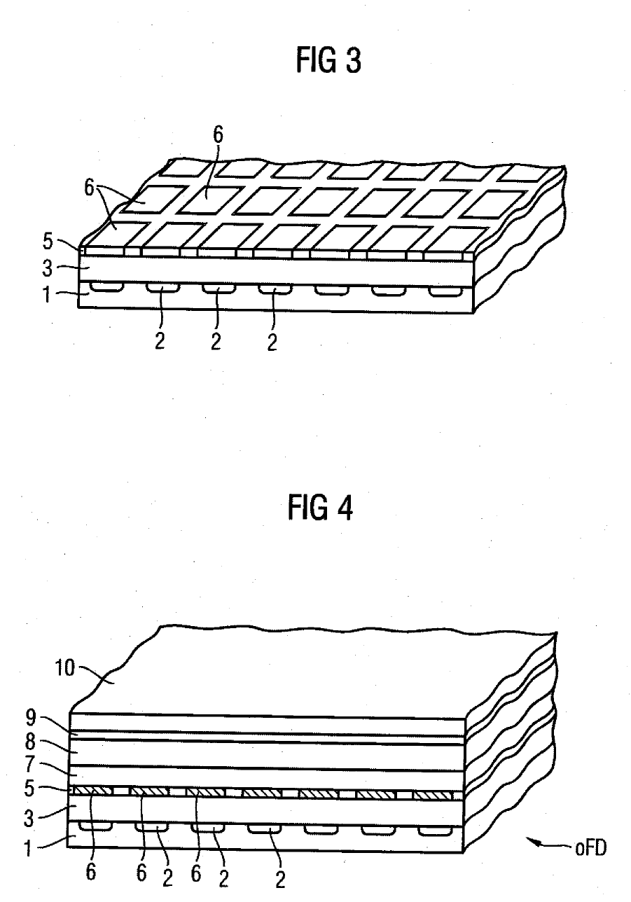

A laminar electrode 5 (shown in FIG. 3) is thereupon applied on the passivation layer 3, which laminar electrode 5 is structured such that it comprises a plurality of sub-electrodes 6 arranged like a matrix. Via the vias 4, each of the sub-electrodes 6 is respectively electrically connected through the passivation layer 3 with a respective transistor 2 of the transistor matrix of the substrate 1.

As shown in FIG. 4, an electron-blocking layer 7 made from an organic material is applied areally, for example via rotation coating (spin coating), scraping or printing techniques. In the case of the present exemplary embodiment, TFB is used as an organic material. The electron-blocking layer 7 is subsequently provided with a photoactive layer 8 made from an organic semiconductor material (P3HT/PCBM in the case of the present exemplary embodiment). A further laminar electrode 9 is thereupon applied on the photoactive layer 8, which laminar electrode 9 is in turn provided with a transparent protective layer. The electrode 9 is produced from an at least semi-transparent material.

Although the present invention was described using a preferred exemplary embodiment, the invention is not limited to this but rather can be modified in many ways. In particular, substrates with other transistors than the a-Si FETs shown in FIGS. 1 through 4 can also be used. The inventive flat panel detector also does not have to be an organic flat panel detector, meaning that the electron-blocking layer 7 and the photoactive layer 8 can also be produced from inorganic materials (for example silicon).

Although further modifications and changes may be suggested by those skilled in the art, it is the intention of the inventors to embody within the patent warranted heron all changes and modifications as reasonably and properly come within the scope of their contribution to the art,

1. Flat panel detector, comprising
a substrate (1) with a transistor matrix (2),
a photodetector with a structured first electrode (5) comprising a plurality of sub-electrodes (6), with a second electrode (9) and with a photoactive layer (8) arranged between the two electrodes (6, 9) and
a passivation layer (3) arranged between the first electrode (5) and the substrate (1).

2. Flat panel detector according to claim 1, in which the passivation layer (3) is applied, planarized and/or structurable on the substrate (1) by means of printing techniques.

3. Flat panel detector according to claim 1 or 2, in which the individual sub-electrodes (6) of the first electrode (5) are contacted through the passivation layer (3) with a respective transistor (2) of the substrate (1) possessing the transistor matrix.

4. Flat panel detector according to any of the claims 1 through 3, in which the photodetector is an organic photodetector (oPD) whose photoactive layer (8) comprises an organic semiconductor material.

5. Flat panel detector according to any of the claims 1 through 4, in which the transistors (2) of the transistor matrix of the substrate (1) comprise a-Si, LTpolySi, pentacene, polymers, ZnO and/or chalcopyrite FETs.
